(19) United States
(12) Patent Application Publication
(10) Pub. No.: US 2019/0037693 A1
(43) Pub. Date: Jan. 31, 2019

(54) PRINTED CIRCUIT BOARD AND METHOD OF FABRICATING THE SAME

(71) Applicant: Samsung Electro-Mechanics Co., Ltd., Suwon-si (KR)

(72) Inventor: Dae-Kyung KANG, Suwon-si (KR)

(73) Assignee: Samsung Electro-Mechanics Co., Ltd., Suwon-si (KR)

(21) Appl. No.: 16/047,416

(22) Filed: Jul. 27, 2018

(30) Foreign Application Priority Data
Jul. 27, 2017 (KR) 10-2017-0095527

(51) Int. Cl. H05K 1/11; H05K 3/00; H05K 1/02; H05K 3/46; H05K 3/42

(52) U.S. Cl. CPC H05K 1/115; H05K 3/0026; H05K 1/0266; H05K 3/4682; H05K 3/4655; H05K 2203/072; H05K 3/425; H05K 2201/09827; H05K 2203/107; H05K 2201/09936; H05K 2203/0723; H05K 3/429

(57) ABSTRACT

A printed circuit board in accordance with a disclosed embodiment may include first insulating layer having first via formed therein and second insulating layer laminated on both surfaces of the first insulating layer and having second via formed therein. The second via may connect first circuit formed on the first insulating layer with second circuit formed on the second insulating layer. A diameter of the second via may become greater toward an inside of the printed circuit board.

### CROSS-REFERENCE TO RELATED APPLICATIONS

This application claims the benefit under 35 USC 119(a) of Korean Patent Application No. 10-2017-0095527, filed with the Korean Intellectual Property Office on Jul. 27, 2017, the disclosure of which is incorporated herein by reference in its entirety.

### BACKGROUND

### 1. Field

The following description relates to a printed circuit board and a method of manufacturing the printed circuit board.

### 2. Description of Related Art

In the course of fabricating a PCB, a deviation in thickness of copper plating may be occurred in a circuit plating process. This plating deviation may cause a deviation in thickness of an insulating layer in a follow-up process and may further cause a deviation in diameter of a via hole.

The diameter of via hole may include a top diameter and a bottom diameter of the via hole. The deviation in the top diameter may cause an eccentricity defect, and the deviation in the bottom diameter may cause a via open defect, deteriorating the reliability of the PCB product.

By obtaining the bottom diameter of the via in order to avoid the reliability defect, the top diameter of the via may be enlarged, possibly increasing the ratio of the eccentricity defect. Moreover, adjusting the processing conditions for obtaining the bottom diameter of the via may cause an increased processing time.

Accordingly, a method of fabricating a printed circuit board is required for simultaneously reducing the deviation in top diameter of the via and the deviation in bottom diameter of the via.

The related art is described in Korean Patent Publication No. 10-2016-0117809 (laid open on Oct. 11, 2016).

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

According to an aspect of the present disclosure, a printed circuit board may include first insulating layer having first via formed therein and second insulating layer laminated on both surfaces of the first insulating layer and having second via formed therein. The second via may connect first circuit formed on the first insulating layer with second circuit formed on the second insulating layer. A diameter of the second via may become greater toward an inside of the printed circuit board.

According to another aspect of the present invention, a method of fabricating a printed circuit board may include: processing first via hole in first insulating layer; forming first circuit on both surfaces of the first insulating layer and forming first via in the first via hole; processing second via hole in second insulating layer; laminating the second insulating layer on the first insulating layer in such a way that a processing surface of the second insulating layer where the second via hole is processed is placed toward the first insulating layer; and forming second circuit on the second insulating layer and forming second via in the second via hole.

Other features and aspects will be apparent from the following detailed description, the drawings, and the claims.

### BRIEF DESCRIPTION OF DRAWINGS

FIG. 1 illustrates a printed circuit board in accordance with a disclosed embodiment of the present disclosure.

FIG. 2 to FIG. 17 illustrate a method of fabricating a printed circuit board in accordance with a disclosed embodiment of the present disclosure.

FIG. 18 illustrates a printed circuit board in accordance with another disclosed embodiment of the present disclosure.

FIG. 19 to FIG. 22 illustrate a method of fabricating a printed circuit board in accordance with another disclosed embodiment of the present disclosure.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Unless otherwise defined, all terms, including technical terms and scientific terms, used herein have the same meaning as how they are generally understood by those of ordinary skill in the art to which the present disclosure pertains. Any term that is defined in a general dictionary shall be construed to have the same meaning in the context of the relevant art, and, unless otherwise defined explicitly, shall not be interpreted to have an idealistic or excessively formalistic meaning.

Identical or corresponding elements will be given the same reference numerals, regardless of the figure number, and any redundant description of the identical or corresponding elements will not be repeated. Throughout the description of the present disclosure, when describing a certain relevant conventional technology is determined to evade the point of the present disclosure, the pertinent detailed description will be omitted. Terms such as “first” and “second” can be used in describing various elements, but the above elements shall not be restricted to the above terms. The above terms are used only to distinguish one element from the other. In the accompanying drawings, some elements may be exaggerated, omitted or briefly illustrated, and the dimensions of the elements do not necessarily reflect the actual dimensions of these elements.

Hereinafter, certain embodiments of the present disclosure will be described in detail with reference to the accompanying drawings.

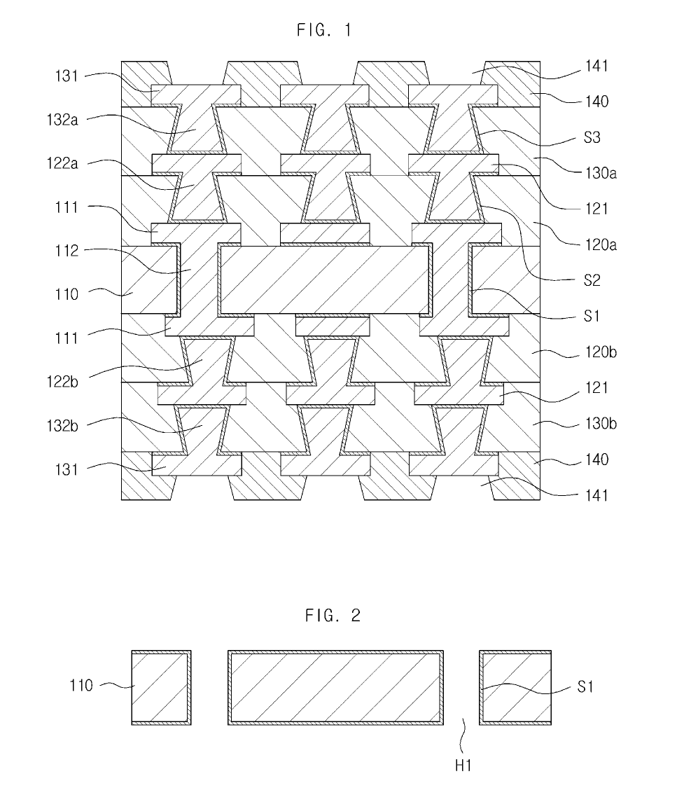

FIG. 1 illustrates a printed circuit board in accordance with a disclosed embodiment of the present disclosure.

The printed circuit board in accordance with a disclosed embodiment of the present disclosure may include first insulating layer 110, first circuit 111, first via 112, second insulating layer 120a, 120b, second circuit 121 and second via 122a, 122b.

The second via 122a, 122b may connect the first circuit 111 with the second circuit 121, and a diameter of the second via 122a, 122b may become greater toward an inside of the printed circuit board.

The first insulating layer 110 may be a plate type made of an insulating material such as resin. The resin may be any one of various materials such as, for example, thermosetting resin and thermoplastic resin, specifically, epoxy resin or polyimide. In this example, the epoxy resin may be, but not limited to, for example, naphthalene epoxy resin, bisphenol A type epoxy resin, bisphenol F type epoxy resin, novolak epoxy resin, cresol novolak epoxy resin, rubber modified epoxy resin, ring-type aliphatic epoxy resin, silicon epoxy resin, nitrogen epoxy resin or phosphor epoxy resin.

The first insulating layer 110 may be Prepreg (PPG), which has fiber stiffener, such as glass cloth, contained in the resin. The first insulating layer 110 may be build-up film having an inorganic filler, such as silica, filled in the resin. Ajinomoto Build-up Film (ABF) may be used for this build-up film.

The first insulating layer 110 may have the first circuit 111 formed thereon and have the first via 112 formed therein.

The first circuit 111 may be a conductor formed and patterned on both surfaces of the first insulating layer 110 to transfer electric signals. The first circuit 111 may be made of a metal such as, for example, copper (Cu), palladium (Pd), aluminum (Al), nickel (Ni), titanium (Ti), gold (Au), platinum (Pt) or an alloy of some of these metals, given the electric conductivity of these metals.

The first via 112 may be formed by penetrating the first insulating layer 110 and interconnect the first circuit 111 formed on both surfaces of the first insulating layer 110. In other words, the first circuit 111 formed on one surface of the first insulating layer 110 and the first circuit formed on the other surface of the first insulating layer 110 may be connected with each other by the via 112.

The first via 112 may be formed by having a conductive layer formed inside first via hole H1, which is shown in FIG. 2. The conductive layer may include, but not limited to, plating layer, conductive paste and conductive ink. The plating layer of the first via 112 may be made of a same material as that of the first circuit 111.

As illustrated in FIG. 1, a diameter of the first via 112 may be constant from the one surface to the other surface of the first insulating layer 110. In this example, being “constant” does not necessarily mean being exactly identical but may mean being substantially identical within a tolerable range of error.

The first via 112 and the first circuit 111 may include first seed layer S1. The first seed layer S1 may be made of a same material as that of the first circuit 111 and the first via 112. The existence of the first seed layer Si may be determined based on a method of forming the first circuit 111 and the first via 112, and particularly, in the case where the first circuit 111 is formed using, for example, the SAP or MSAP technique, the first seed layer S1 may be included in the first circuit 111 and the first via 112.

The first circuit 111 and the first via 112 illustrated in FIG. 1 may have been formed through the SPA technique. Although the present disclosure is described with reference to FIG. 1, the first circuit 111 and the first via 112 do not necessarily have to be formed through the SAP technique, and the present disclosure is not meant to exclude other techniques, including the MSAP technique.

The first seed layer S1 may be formed on an inner wall of the first via hole H1 and on the both surfaces of the first insulating layer 110. In this example, the conductive layer of the first via 112 may include the first seed layer S1, which is formed using electroless plating, and electroplated layer, which is formed using electroplating.

The second insulating layer 120a, 120b may be a plate type made of an insulating material such as resin. The resin may be any one of various materials such as, for example, thermosetting resin and thermoplastic resin, specifically, epoxy resin or polyimide. In this example, the epoxy resin may be, but not limited to, for example, naphthalene epoxy resin, bisphenol A type epoxy resin, bisphenol F type epoxy resin, novolak epoxy resin, cresol novolak epoxy resin, rubber modified epoxy resin, ring-type aliphatic epoxy resin, silicon epoxy resin, nitrogen epoxy resin or phosphor epoxy resin.

The second insulating layer 120a, 120b may be build-up film having an inorganic filler, such as silica, filled in the resin. Ajinomoto Build-up Film (ABF) may be used for this build-up film.

The second insulating layer 120a, 120b may be made of a same material as, or a material different from, that of the first insulating layer 110. Particularly, the first insulating layer 110 may be Prepreg, and the second insulating layer 120a, 120b may be the build-up film.

The second insulating layer 120a, 120b may be laminated on the first insulating layer 110, and may be distinguished into an insulating layer 120a laminated on an upper side (e.g., one surface side) of the first insulating layer 110 and an insulating layer 120b laminated on a lower side (e.g., the other surface side) of the first insulating layer 110.

The second insulating layer 120a, 120b may have the second circuit 121 formed thereon and have the second via 122a, 122b formed therein.

The second circuit 121 may be a conductor formed and patterned on the second insulating layer 120a, 120b to transfer electric signals. The second circuit 121 may be made of a metal such as, for example, copper (Cu), palladium (Pd), aluminum (Al), nickel (Ni), titanium (Ti), gold (Au), platinum (Pt) or an alloy of some of these metals, given the electric conductivity of these metals. The second circuit 121 may be made of a same metal as that of the first circuit 111.

The second via 122a, 122b may be formed by penetrating the second insulating layer 120a, 120b and interconnect the first circuit 111 with the second circuit 121.

The second via 122a, 122b may be formed by having a conductive layer formed inside second via hole H2. The conductive layer may include, but not limited to, plating layer, conductive paste and conductive ink.

As illustrated in FIG. 1, the diameter of the second via 122a, 122b may become greater toward the inside of the printed circuit board. In other words, the diameter of the second via 122a, 122b may become greater from the second insulating layer 120a, 120b to the first insulating layer 110.

The second via 122a, 122b may be distinguished into a via 122a formed on an upper side (e.g., one surface side) of the first insulating layer 110 and a via 122b formed on a lower side (e.g., the other surface side) of the first insulating layer 110.

The via 122a formed on the upper side (e.g., the one surface side) of the first insulating layer 110 may have a diameter increasing from a top to a bottom thereof and thus may have a trapezoidal shape of cross section.

On the other hand, the via 122b formed on the lower side (e.g., the other surface side) of the first insulating layer 110 may have a diameter decreasing from a top to a bottom thereof and thus may have an inverse trapezoidal shape of cross section.

The shape of the via 122a formed on the upper side (e.g., the one surface side) of the first insulating layer 110 and the shape of the via 122b formed on the lower side (e.g., the other surface side) of the first insulating layer 110 may be symmetrical with each other about the first insulating layer 110. In this example, being “symmetrical” means the shape of a via being symmetrical with the shape of another via and does not mean, for example, the position and number of the vias being symmetrical. The position and number of the vias may be symmetrical or asymmetrical about the first insulating layer 110.

The second circuit 121 and the second via 122a, 122b may include second seed layer S2. The second seed layer S2 may be made of a same material as that of the second circuit 121 and the second via 122a, 122b. The second seed layer S2 may be formed on an inner wall (e.g., inside surface) and a lower portion (e.g., bottom surface) of the second via hole H2 and on the second insulating layer 120a, 120b. In this example, the conductive layer of the second via 122a, 122b may include seed layer, which is formed using electroless plating, and electroplated layer, which is formed using electroplating.

The printed circuit board in accordance with the disclosed embodiment of the present disclosure may further include third insulating layer 130a, 130b, third circuit 131, third via 132a, 132b and solder resist 140.

The third insulating layer 130a, 130b may be a plate type made of an insulating material such as resin. The third insulating layer 130a, 130b may be made of a same material as that of the second insulating layer 120a, 120b. For example, the third insulating layer 130a, 130b may be build-up film, which is the same as the second insulating layer 120a, 120b.

The third insulating layer 130a, 130b may be laminated on the second insulating layer 120a, 120b and may be distinguished into an insulating layer 130a laminated above the second insulating layer 120a and an insulating layer 130b laminated below the second insulating layer 120b.

The third insulating layer 130a, 130b may have the third circuit 131 formed thereon and have the third via 132a, 132b formed therein.

The third circuit 131 may be a conductor formed and patterned on the third insulating layer 130a, 130b to transfer electric signals. The third circuit 131 may be made of a metal such as, for example, copper (Cu), palladium (Pd), aluminum (Al), nickel (Ni), titanium (Ti), gold (Au), platinum (Pt) or an alloy of some of these metals, given the electric conductivity of these metals. The third circuit 131 may be made of a same metal as that of the first circuit 111 and the second circuit 121.

The third via 132a, 132b may be formed by penetrating the third insulating layer 130a, 130b and interconnect the second circuit 121 with the third circuit 131.

The third via 132a, 132b may be formed by having a conductive layer formed inside third via hole H3. The conductive layer may include, but not limited to, plating layer, conductive paste and conductive ink.

As illustrated in FIG. 1, the diameter of the third via 132a, 132b may become greater toward the inside of the printed circuit board. In other words, the diameter of the third via 132a, 132b may become greater from the third insulating layer 130a, 130b to the second insulating layer 120a, 120b.

The third via 132a, 132b may be distinguished into a via 132a formed on an upper side of the second insulating layer 120a and a via 132b formed on a lower side of the second insulating layer 120b.

The via 132a formed on the upper side of the second insulating layer 120a may have a diameter increasing from a top to a bottom thereof and thus may have a trapezoidal shape of cross section. The shape of the via 132a formed on the upper side of the second insulating layer 120a may be the same as that of the via 122a formed on the upper side (e.g., the one surface side) of the first insulating layer 110.

On the other hand, the via 132b formed on the lower side of the second insulating layer 120b may have a diameter decreasing from a top to a bottom thereof and thus may have an inverse trapezoidal shape of cross section. The shape of the via 132b formed on the lower side of the second insulating layer 120b may be the same as that of the via 122b formed on the lower side (e.g., the other surface side) of the first insulating layer 110.

Just as the shape of the via 122a formed on the upper side (e.g., the one surface side) of the first insulating layer 110 and the shape of the via 122b formed on the lower side (e.g., the other surface side) of the first insulating layer 110 may be symmetrical with each other about the first insulating layer 110, the shape of the via 132a formed on the upper side of the second insulating layer 120a and the shape of the via 132b formed on the lower side of the second insulating layer 120b may be symmetrical with each other about the first insulating layer 110.

The third circuit 131 and the third via 132a, 132b may include third seed layer S3. The third seed layer S3 may be made of a same material as that of the third circuit 131 and the third via 132a, 132b. The third seed layer S3 may be formed on an inner wall (e.g., inside surface) and a lower portion (e.g., bottom surface) of the third via hole H3 and on the third insulating layer 130a, 130b. In this example, the conductive layer of the third via 132a, 132b may include the third seed layer S3, which is formed using electroless plating, and electroplated layer, which is formed using electroplating.

Basically, the second insulating layer 120a, 120b and the third insulating layer 130a, 130b may be regarded as the same element laminated on different layers from each other. Fourth insulating layer, fifth insulating layer and so on may be successively laminated, similarly to the second insulating layer 120a, 120b and the third insulating layer 130a, 130b.

The solder resist 140 may be formed on an outermost insulating layer to protect an outermost circuit. In this example, it will be assumed that the outermost insulating layer is the third insulating layer 130a, 130b, for the purpose of description. Nonetheless, this assumption is not meant to exclude the possibility of the outermost insulating layer being the above-described second insulating layer 120a, 120b or the fourth insulating layer, the fifth insulating layer, and so on.

The solder resist 140 may be made of a photosensitive insulating material. The solder resist 140 may be formed with an opening 141, through which the third circuit 131 may be exposed. A diameter of the opening 141 may become smaller toward the inside of the printed circuit board. As a result, the opening 141 of the solder resist 140 may have a shape inversed from the adjacent third via 132a, 132b. Specifically, the opening 141 placed on the upper side of the first insulating layer 110 may have the cross-sectional shape of an inverse trapezoid while the third via 132a may have the cross-sectional shape of a regular trapezoid. On the contrary, the opening 141 placed on the lower side of the first insulating layer 141 may have the cross-sectional shape of a regular trapezoid while the third via 132b may have the cross-sectional shape of an inverse trapezoid.

The exposed region of the third circuit 131 may become a wire-bonding pad or a solder ball pad for connecting an electronic component. This pad may have a surface treatment layer formed thereon. The surface treatment layer may be made of metal or nonmetal in order to prevent the pad from oxidation.

FIG. 2 to FIG. 17 illustrate a method of fabricating a printed circuit board in accordance with a disclosed embodiment of the present disclosure.

Referring to FIG. 2, first via hole H1 is formed in first insulating layer 110.

The first insulating layer 110 may be made of resin, which may be any one of various materials such as, for example, thermosetting resin and thermoplastic resin, specifically, epoxy resin or polyimide. In this example, the epoxy resin may be, but not limited to, for example, naphthalene epoxy resin, bisphenol A type epoxy resin, bisphenol F type epoxy resin, novolak epoxy resin, cresol novolak epoxy resin, rubber modified epoxy resin, ring-type aliphatic epoxy resin, silicon epoxy resin, nitrogen epoxy resin or phosphor epoxy resin.

The printed circuit board in accordance with the disclosed embodiment may be formed using the SAP technique, in which case the first insulting layer 110 may be treated with catalyst on both surface thereof. Particularly, the both surfaces of the first insulating layer 110 may be treated with palladium (Pd) catalyst. The catalyst treatment may include allowing the catalyst (e.g., Pd—Sn colloid or Pd complex compound) to be adsorbed onto the both surfaces of the first insulating layer 110 and then obtaining metal palladium by reducing the catalyst. This is a pre-process for forming a seed layer through electroless plating. Moreover, the first insulating layer 110 may have unevenness lightly formed through a roughness treatment on the both surfaces of the first insulating layer 110.

The first via hole H1 may be formed using a drill bit. A diameter of the first via hole H1 formed using the drill bit may be constant from one surface to an opposite surface of the first insulating layer 110.

First seed layer S1 may be formed on an inner wall of the first via hole H1 and on both surfaces of the first insulating layer 110. As described above, the first seed layer S1 may be formed through electroless plating, in which copper sulfate (CuSO₄), for example, may be used as a metallic salt, which is a major constituent of a plating solution, and formaldehyde or dimethylamine borane, for example, may be used as a reducing agent. Moreover, palladium, for example, may be uses as the catalyst. The formed first seed layer S1 may have a thickness of about 0.5 to 1 um.

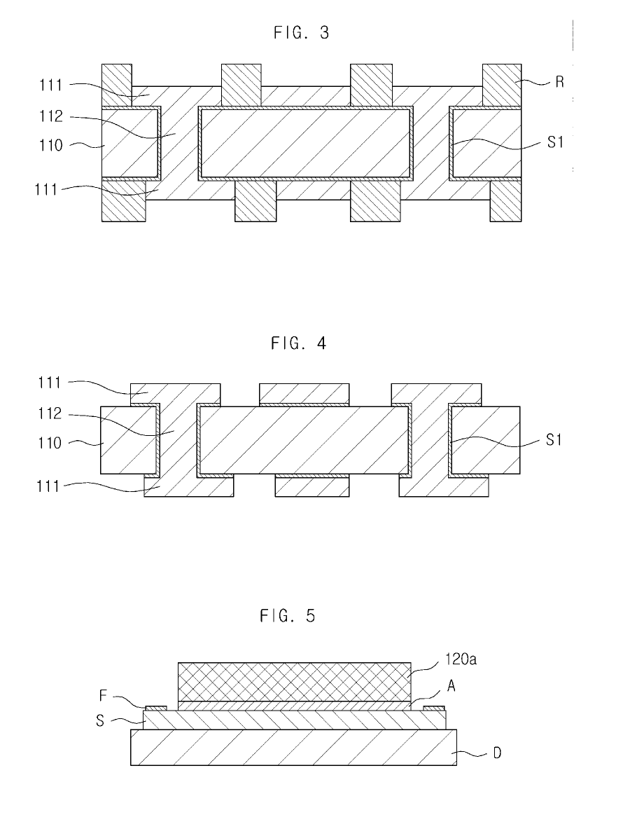

Referring to FIG. 3 and FIG. 4, first circuit 111 and first via 112 may be formed. The first circuit 111 and the first via 112 may be formed on the first seed layer S1 through electroplating using patterned plating resist R. That is, plating may be performed at areas where the plating resist R is not placed. A thickness of the first circuit 111 may be about 10 to 15 um.

As illustrated in FIG. 4, once the plating of the first circuit 111 and the first via 112 is completed, the plating resist R may be peeled off. Moreover, unnecessary portions of the first seed layer S1 may be removed through etching. The first seed layer S1 may remain unremoved corresponding to the first circuit 111.

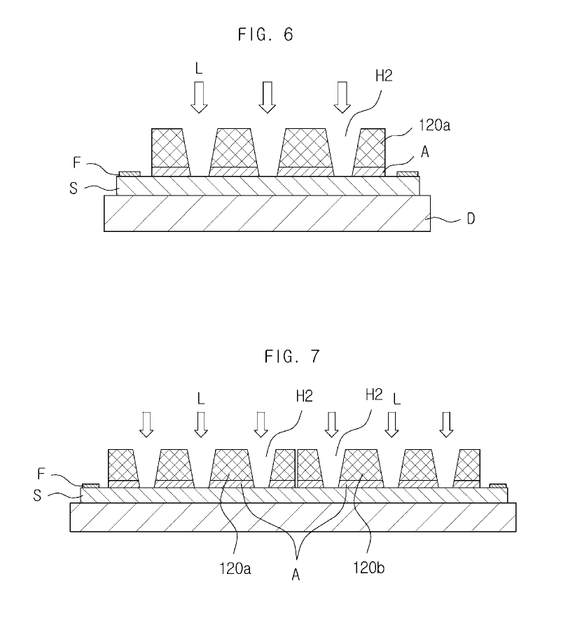

Referring to FIG. 5 and FIG. 6, second insulating layer 120a, 120b may be prepared, and second via hole H2 may be formed in the second insulating layer 120a.

As illustrated in FIG. 5, the second insulating layer 120a may be disposed on support plate S, and adhesive layer A may be interposed between the second insulating layer 120a and the support plate S. In other words, the second insulating layer may be adhered to the support plate S. The support plate S may be a metal, such as SUS, having a high rigidity, and the second insulating layer 120a may be a jig. The support plate S may be sitting on via hole processing die D.

As illustrated in FIG. 6, the second via hole H2 may be formed through a laser process, in which via hole is formed using a laser drill. The laser may be CO₂ laser.

Once laser L is irradiated onto the second insulating layer 120a, the second insulating layer 120a may be removed corresponding to areas of laser L irradiation. A surface of the second insulating layer 120a onto which the laser L is irradiated may be referred to as a processing surface.

By the laser process, a hole may be formed through an entire thickness of the second insulating layer 120a and may be further formed in the adhesive layer A. Alternatively, a groove (e.g., an unpierced hole) may be formed at an area of the adhesive layer A corresponding to a position of the second via hole H2. That is, by the laser L irradiation, the area of the adhesive layer A corresponding to the position of the second via hole H2 may be removed.

In this example, since no residual insulating layer remains in the second via hole H2, no follow-up desmear process may be required, thereby reducing the number of processes.

Meanwhile, a diameter of the second via hole H2 may become smaller from the processing surface to an opposite surface. This is because laser energy is decreased away from the processing surface.

Referring to FIG. 7, a plurality of second insulating layers 120a, 120b may be disposed with the support plate S. By adjusting laser processing positions, the plurality of second insulating layers 120a, 120b may be formed with via holes at positions identical to one another or at positions different from one another. That is, it is possible to form a plurality of identical insulating layers or a plurality of insulating layers different from one another simultaneously through a single laser process.

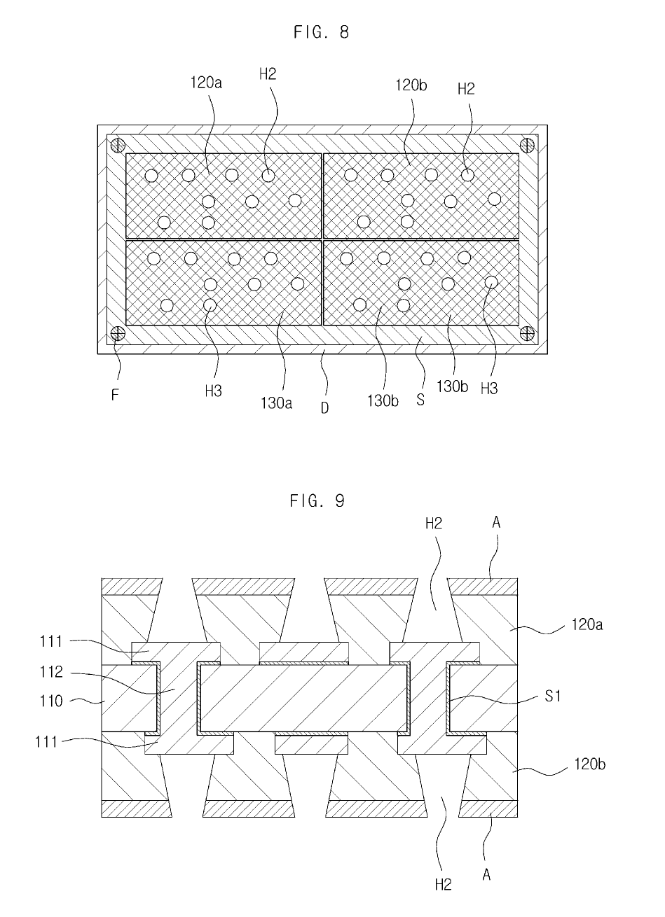

Meanwhile, as illustrated in FIG. 8, the second insulating layer 120a, 120b may be disposed together with third insulating layer 130a, 130b on the support plate S. In this manner, the plurality of second insulating layers 120a, 120b and third insulating layers 130a, 130b, maybe as well as a plurality of fourth insulating layers, fifth insulating layers, and so on, may be disposed together on the support plate S and processed simultaneously.

Referring to FIG. 5 to FIG. 8, the support plate S may be provided with fiducial marks F, which are marks for alignment during the laser process. The fiducial marks F may be provided in various forms, such as, for example, protrusions or grooves at four corners of the support plate F.

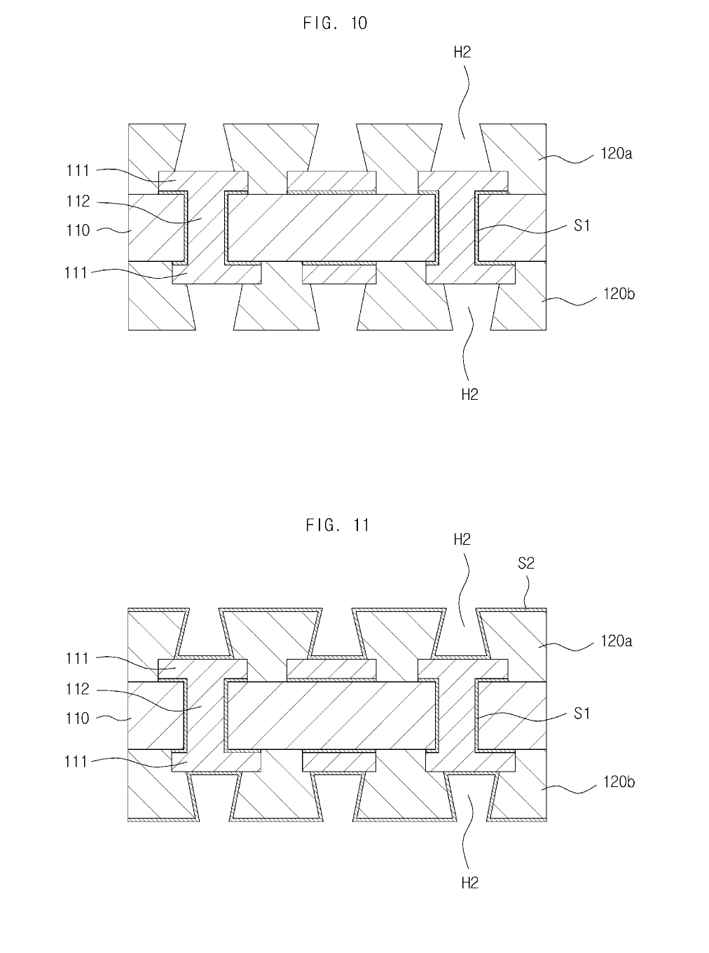

Referring to FIG. 9 and FIG. 10, the second insulating layers 120a, 120b having the second via holes H2 formed therein may be laminated on the first insulating layer 110. The second insulating layers 120a, 120b may be laminated in such a way that the processing surfaces of the second insulating layers 120a, 120b where the second via holes H2 are processed are placed toward the first insulating layer 110.

Meanwhile, the two insulating layers 120a, 120b may be laminated simultaneously or sequentially on both surfaces of the first insulating layer 110, respectively.

The laminating of the second insulating layers 120a, 120b on the first insulating layer 110 may include removing the support plate S from the second insulating layer 120a, 120b, laminating the second insulating layer 120a, 120b on the first insulating layer 110, and removing the adhesive layer A from the second insulating layer 120a, 120b.

In the removing of the support plate S from the second insulating layer 120a, 120b, the support plate S may be separated from the second insulating layer 120a, 120b and the adhesive layer A.

In the laminating of the second insulating layer 120a, 120b on the first insulating layer 110, the second insulating layer 120a, 120b may be laminated on the first insulating layer 110, and then the first insulating layer and the second insulating layer 120a, 120b may be pressed to each other by use of, for example, laminator.

As illustrated in FIG. 9, when the second insulating layer 120a, 120b is disposed on the first insulating layer 110, the adhesive layer A may be exposed toward an outside because the processing surface of the second insulating layer 120a, 120b where the second via hole H2 is processed is placed toward the first insulating layer 110.

Referring to FIG. 10, after the second insulating layer 120a, 120b is laminated together with the adhesive layer A on the first insulating layer 110, the adhesive layer A may be removed.

Moreover, since the processing surface of the second insulating layer 120a, 120b is placed toward the first insulating layer 110, the diameter of the second via hole H2 may become smaller toward an inside of the printed circuit board.

Meanwhile, the laminating of the second insulating layer 120a, 120b on the first insulating layer 110 may include removing the support plate S from the second insulating layer 120a, 120b, removing the adhesive layer A from the second insulating layer 120a, 120b, and laminating second insulating layer 120a, 120b on the first insulating layer 110. That is, after removing the adhesive layer A first, the second insulating layer 120a, 120b and the first insulating layer 110 may be laminated with each other.

Referring to FIG. 11, second seed layer S2 may be formed inside the second via hole H2 and on the second insulating layer 120a, 120b. The second seed layer S2 may be formed through electroless plating, of which details are identical to the forming of the first seed layer S1.

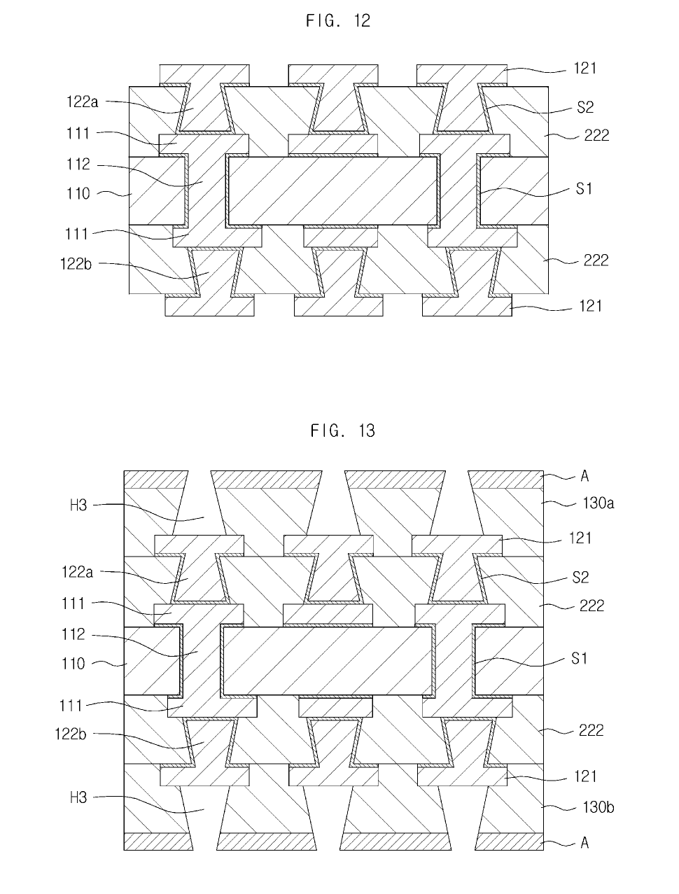

Referring to FIG. 12, second via 122a, 122b may be formed in the second via hole H2, and second circuit 121 may be formed on the second insulating layer 120a, 120b. The second via 122a, 122b may connect the first circuit 111 with the second circuit 121. The second via 122a, 122b and the second circuit 121 may be formed through electroplating. Later, by removing unnecessary portions of the second seed layer S2 through etching, the second seed layer S2 may remain corresponding to the second circuit 121.

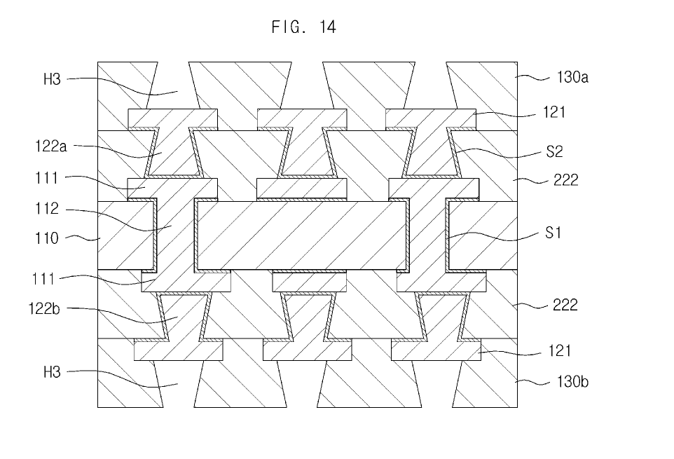

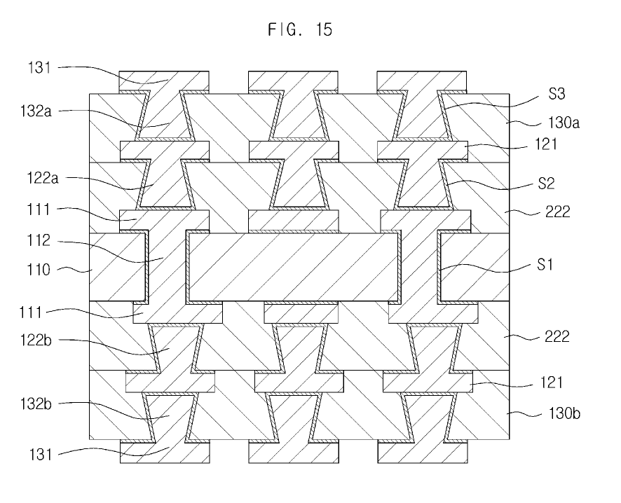

Referring to FIG. 13 and FIG. 14, third insulating layer 130a, 130b may be laminated on the second insulating layer 120a, 120b in the same way as the second insulating layer 120a, 120b. In this example as well, processing surface of the third insulating layer 130a, 130b where third via hole H3 is processed may be placed toward the second insulating layer 120a, 120b, and thus a diameter of the third via hole H3 may become smaller toward the inside of the printed circuit board.

As described above, the third via hole H3 of the third insulating layer 130a, 130b may be processed in the same process for forming the second via hole H2 of the second insulating layer 120a, 120b. Moreover, the first insulating layer 110, the second insulating layer 120a, 120b and the third insulating layer 130a, 130b may be simultaneously laminated, in which case the first insulating layer 110, the second insulating layer 120a, 120b and the third insulating layer 130a, 130b may be laminated together after the adhesive layer A of the second insulating layer 120a, 120b and adhesive layer A of the third insulating layer 130a, 130b are completely removed.

Referring to FIG. 15, third via 132a, 132b and third circuit 131 may be formed. The third via 132a, 132b may connect the second circuit 121 with the third circuit 131. The third circuit 131 may include third seed layer S3. A series of processes for forming the third circuit 131 and the third via 132a, 132b may be identical with the processes for forming the second circuit 121 and the second via 122a, 122b.

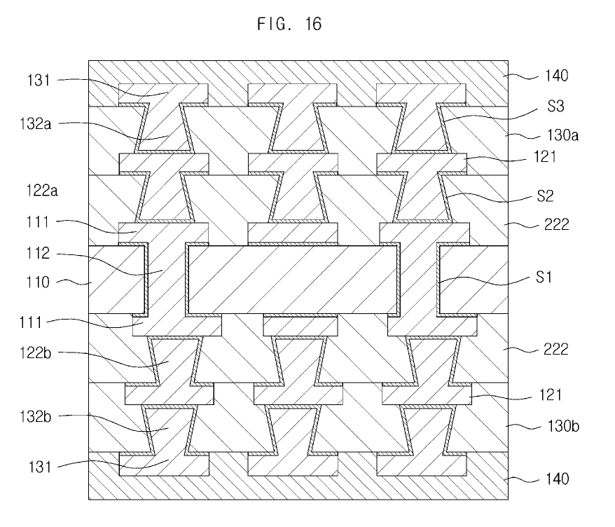

Referring to FIG. 16, solder resist 140 may be formed. The solder resist 140 may be configured for various functions, including protecting outermost circuits, providing insulation between the outermost circuits and preventing solder from being attached when installing a component. The solder resist 140 may be mainly made of photosensitive resin. Accordingly, the solder resist 140 may be hardened by light (e.g., UV rays).

In FIG. 16, the solder resist 140 may be coated on the third insulating layer 130a, 130b while covering the third circuit 131. Coating the solder resist 140 may be performed by spreading the solder resist 140 on the third insulating layer 130a, 130b using, for example, screen coating or roll coating, and then drying the spread solder resist 140. The screen coating refers to coating the solder resist 140 by pressing and moving the solder resist 140 by use of a squeeze, and the roll coating refers to coating the solder resist 140 on both surfaces of the printed circuit board by transporting the printed circuit board between two rolls. In addition, the solder resist 140 may be coated by use of, for example, curtain coating or spray coating.

Later, the coated solder resist 140 may be pre-dried to evaporate solvent contained in the solder resist 140 and maintain a flat state of coating.

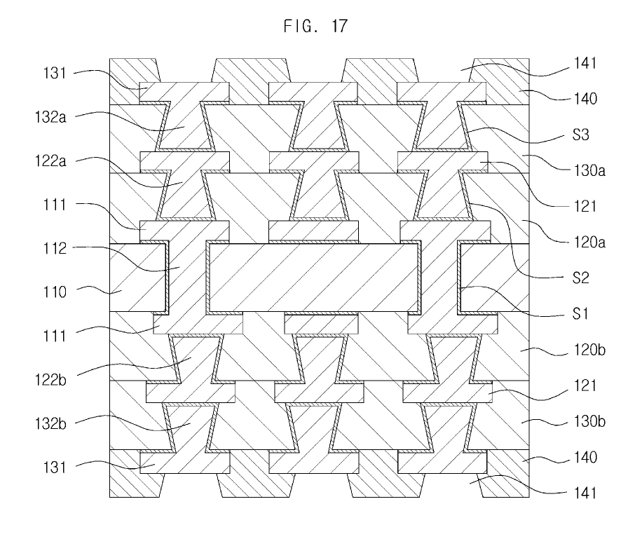

Referring to FIG. 17, opening 141 is formed in the solder resist 140. The opening 141 may be formed through exposure and development processes. As the solder resist 140 is photosensitive resin having a negative property, aligning patterned work film on the solder resist 140 and irradiating light, such as UV rays, selectively may result in areas of irradiation (e.g., exposed area) being photo-cured. Later, unexposed areas, which are not cured, may be removed during the development.

A diameter of the opening 141 may become smaller toward the inside of the printed circuit board because optical energy may decrease into the opening 141.

After the opening 141 is formed in the solder resist 140, the rest of the solder resist 140 is fully cured through a cure process.

The third circuit 131 may be partially exposed through the opening 141, and the exposed portion may become a pad, on which surface treatment layer may be formed.

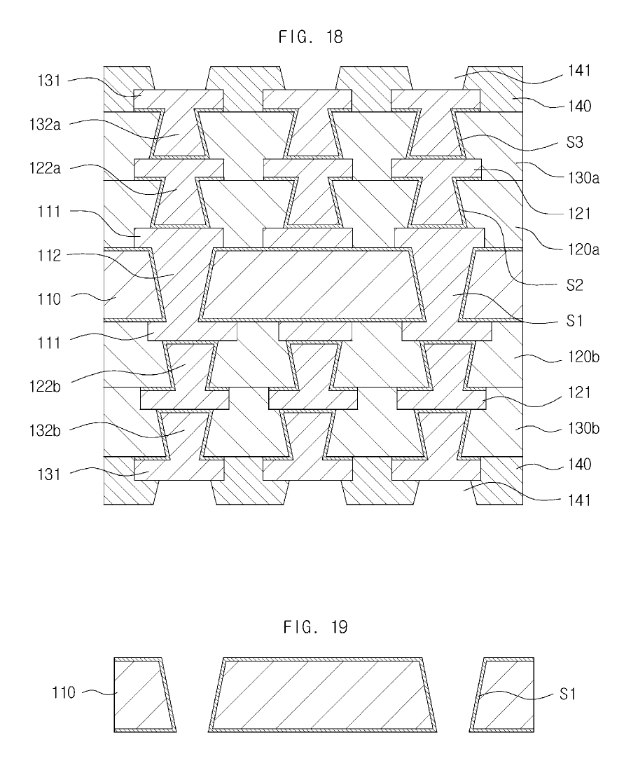

FIG. 18 illustrates a printed circuit board in accordance with another disclosed embodiment of the present disclosure.

The printed circuit board in accordance with the another disclosed embodiment of the present disclosure may include first insulating layer 110, first circuit 111, first via 112, second insulating layer 120a, 120b, second circuit 121 and second via 122a, 122b.

The second via 122a, 122b may connect the first circuit 111 with the second circuit 121, and a diameter of the second via 122a, 122b may become greater toward an inside of the printed circuit board.

The printed circuit board in accordance with the another disclosed embodiment illustrated in FIG. 18 may be nearly identical with the printed circuit board in accordance with the disclosed embodiment illustrated in FIG. 1, except for the shape of the first via 112.

Specifically, while the diameter of the first via 112 is substantially constant from the one surface to the other surface of the first insulating layer 110 in FIG. 1, a diameter of the first via 112 in FIG. 18 may become smaller from one surface to the other surface of the first insulating layer 110. This difference in diameter may be understood to be caused by a difference in the method of forming the first via 112.

The remaining elements are identical with the above description and thus will not be redundantly described herein.

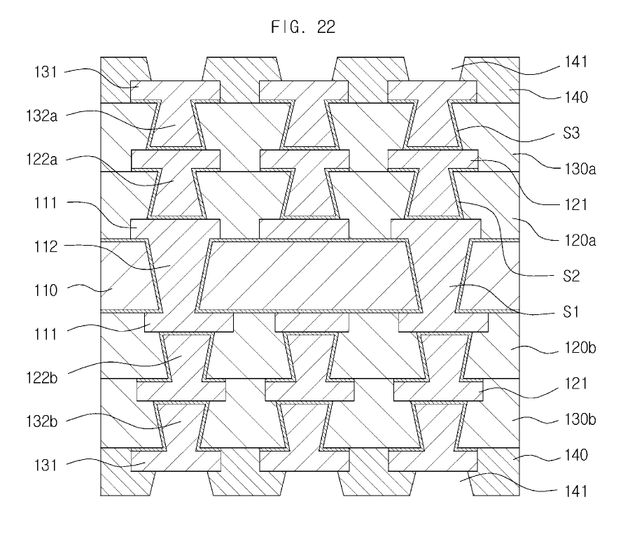

FIG. 19 to FIG. 22 illustrate a method of fabricating a printed circuit board in accordance with another disclosed embodiment of the present disclosure.

Referring to FIG. 19, first via hole H1 may be formed using a laser drill. The first via hole H1 may be formed by laser irradiation, and a diameter of the first via hole H1 formed by laser irradiation may become smaller from one surface to the other surface of first insulating layer 110. In this example, the one surface of the first insulating layer 110 may become a processing surface of the first insulating layer 110 where the first via hole H1 is processed.

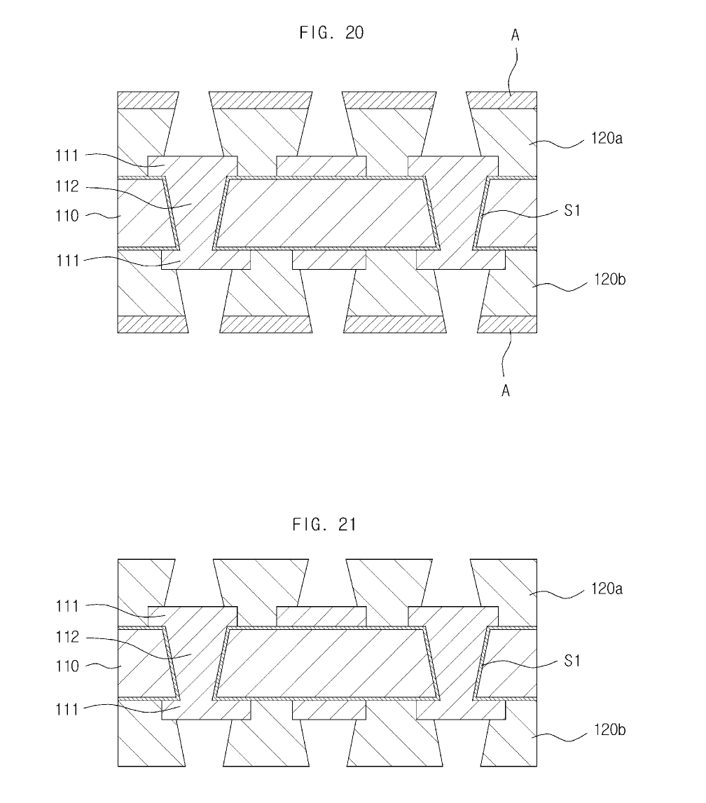

The steps of fabricating the printed circuit board thereafter are identical with the earlier description. Specifically, second via hole H2 may be processed by disposing second insulating layer 120a, 120b on support plate S, and then the second insulating layer 120a, 120b may be laminated on the first insulating layer 110 in such a way that a processing surface of the second insulating layer 120a, 120b where second via hole H2 is processed may be placed toward the first insulating layer 110 (FIG. 20). Adhesive layer A having been attached to the second insulating layer 120a, 120b may be removed; second via 122a, 122b and second circuit 121 may be formed; third via hole H3 may be formed in third insulating layer 130a, 130b in the same manner; the third insulating layer 130a, 130b may be laminated on the second insulating layer 120a, 120b; and third via 132a, 132b and third circuit 131 may be formed. Later, solder resist 140 and opening 141 may be formed (FIG. 21).

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A printed circuit board, comprising:
first insulating layer having first via formed therein; and
second insulating layer laminated on both surfaces of the first insulating layer and having second via formed therein,
wherein the second via connects first circuit formed on the first insulating layer with second circuit formed on the second insulating layer, and
wherein a diameter of the second via becomes greater toward an inside of the printed circuit board.

2. The printed circuit board as set forth in claim 1, wherein a diameter of the first via is constant from one surface to the other surface of the first insulating layer.

3. The printed circuit board as set forth in claim 1, wherein a diameter of the first via becomes smaller from one surface to the other surface of the first insulating layer.

4. The printed circuit board as set forth in claim 1, further comprising solder resist laminated on the second insulating layer,
wherein the solder resist has opening formed therein, and
wherein a diameter of the opening becomes smaller toward the inside of the printed circuit board.

5. A method of fabricating a printed circuit board, comprising:
processing first via hole in first insulating layer;
forming first circuit on both surfaces of the first insulating layer and forming first via in the first via hole;
processing second via hole in second insulating layer;
laminating the second insulating layer on the first insulating layer in such a way that a processing surface of the second insulating layer where the second via hole is processed is placed toward the first insulating layer; and
forming second circuit on the second insulating layer and forming second via in the second via hole.

6. The method as set forth in claim 5, wherein a diameter of the second via hole becomes smaller from the processing surface of the second insulating layer to an opposite surface of the second insulating layer.

7. The method as set forth in claim 5, wherein the processing of the second via hole in the second insulating layer comprises:
disposing the second insulating layer by interposing adhesive layer between the second insulating layer and support plate; and
forming second via hole by irradiating laser onto the processing surface of the second insulating layer.

8. The method as set forth in claim 7, wherein, in the disposing of the second insulating layer by interposing the adhesive layer between the second insulating layer and the support plate, the second insulating layer is provided in plurality.

9. The method as set forth in claim 7, wherein fiducial marks for laser irradiation are provided on the support plate.

10. The method as set forth in claim 7, wherein, in the forming of the second via hole, an area of the adhesive layer corresponding to a position of the second via hole is removed by laser irradiation.

11. The method as set forth in claim 7, wherein the laminating of the second insulating layer on the first insulating layer comprises:
removing the support plate from the second insulating layer;
laminating the second insulting layer on the first insulating layer; and
removing the adhesive layer from the second insulating layer.

12. The method as set forth in claim 5, further comprising:
forming solder resist on the second insulating layer; and
forming opening in the solder resist.

13. The method as set forth in claim 12, wherein the forming of the opening in the solder resist comprises selectively exposing and developing the solder resist.

14. The method as set forth in claim 13, wherein a diameter of the opening becomes smaller toward an inside of the printed circuit board.

15. The method as set forth in claim 5, wherein, in the processing of the first via hole in the first insulating layer, the first via hole is formed by drill bit or laser irradiation.
